(19) United States
(12) Patent Application Publication
(10) Pub. No.: US 2009/0174493 A1
(43) Pub. Date: Jul. 9, 2009

(54) ADJUSTABLE INDUCTOR AND WIDEBAND VOLTAGE CONTROLLED OSCILLATOR

(76) Inventors: Sang-yoon Jeon, Seoul (KR); Heung-bae Lee, Gyeonggi-do (KR); Choong-yul Cha, Gyeonggi-do (KR); Hee-mun Bang, Seoul (KR); Sung-jae Jung, Seoul (KR); Kyu-don Choi, Gyeonggi-do (KR)

Correspondence Address: MCNEELY BODENDORF LLP, P.O. BOX 34175, WASHINGTON, DC, 20043, US

(21) Appl. No.: 12/105,599

(22) Filed: Apr. 18, 2008

(30) Foreign Application Priority Data
Jan. 9, 2008 (KR) 2008-0002514

(51) Int. Cl. H03B 5/08; H01F 21/00

(52) U.S. Cl. 331/181; 336/145; 331/167

(57) ABSTRACT

An adjustable inductor includes a first conductor line to receive an alternating current (AC) signal, a second conductor line configured in a loop arrangement, to generate an inducting current upon receiving the AC signal at the first conductor line, and a switch to adjust an inductance of the first conductor line by switching a loop connection of the second conductor line according to an external control signal.

### CROSS-REFERENCE TO RELATED APPLICATIONS

This application claims the benefit under 35 U.S.C. §119(a) of a Korean Application No. 2008-2514, filed Jan. 9, 2008 in the Korean Intellectual Property Office, the disclosure of which is incorporated herein by reference.

### TECHNICAL FIELD

The following description relates to an adjustable inductor and a wideband voltage controlled oscillator, and more particularly, to an adjustable inductor to vary inductance according to an external control signal and a wideband voltage controlled oscillator using the same.

### BACKGROUND

Semiconductor chips are generally employed in communication devices such as a portable terminal to realize a radio frequency (RF) communication circuit. An inductor element may be considered important among these semiconductor elements. Particularly, a voltage controlled oscillator may be considered an essential element to construct a communication circuit. A demand for a smaller inductor which can provide higher quality factor is increasing.

Digital televisions are now in wide use. More and more image display apparatuses such as TVs have been developed to provide a mixture of analog and digital broadcast with increased efficiency. One example of such analog-digital compatible image display apparatus is built-in DTV. The built-in DTV is capable of receiving broadcast, either analog or digital, through antenna and outputting the received broadcast.

In order to provide analog broadcast and digital broadcast at the same time, a conventional digital TV employs a tuner that includes a plurality of voltage controlled oscillators for each of required bandwidths, to output particular bandwidth according to switching. However, the presence of a plurality of voltage controlled oscillators increases the product price, burdening customers and imposing much limitation in space and design.

### SUMMARY

In one aspect, there is provided an adjustable inductor which provides an increased range of inductance variance, and a voltage controlled oscillator having the same.

In another aspect, there is provided an adjustable inductor including a first conductor line to receive an alternating current (AC) signal, a second conductor line configured in a loop arrangement, to generate an inducting current upon receiving the AC signal at the first conductor line, and a switch to adjust an inductance of the first conductor line by switching a loop connection of the second conductor line according to an external control signal.

The first conductor line may be arranged within the second conductor line and configured in a loop arrangement.

The first conductor line may be configured in a symmetrical arrangement, both vertically and horizontally, with reference to an imaginary line crossing a center.

The first conductor line may be arranged co-planar with the second conductor line, and configured in a multi-spiral structure.

The second conductor line may be configured in a symmetrical arrangement, both vertically and horizontally, with reference to an imaginary line crossing a center.

The adjustable inductor may further include a substrate to support the first and second conductor lines, wherein the first and second conductor lines are arranged co-planar with each other.

The switch may switch so that the second conductor line becomes a closed loop when the switch is turned on in response to the external control signal, and becomes an open loop when the switch is turned off in response to the external control signal.

In still another aspect, there is provided a wideband voltage controlled oscillator including an adjustable capacitor, an adjustable inductor to provide an inductance in response to an alternating current (AC) signal, and to vary the inductance by selectively using an inducing current generated in response to the AC signal, and an adjuster to vary an oscillation frequency by varying a capacitance of the adjustable capacitor and an inductance of the adjustable inductor.

The adjustable inductor may include a first conductor line to receive the AC signal, a second conductor line configured in a loop arrangement, to generate an inducing current in response to the AC signal received at the first conductor line, and a switch to adjust an inductance of the first conductor line, by switching a loop connection of the second conductor line in accordance with a control signal applied from the adjuster.

The first conductor line may be arranged within the second conductor line, and configured in a loop arrangement.

The first conductor line may be configured in a symmetrical arrangement, both vertically and horizontally, with reference to an imaginary line crossing a center.

The first conductor line may be arranged co-planar with the second conductor line, and configured in a multi-spiral structure.

The second conductor line may be configured in a symmetrical arrangement, both vertically and horizontally, with reference to an imaginary line crossing a center.

The adjustable inductor may further comprise a substrate to support the first and second conductor lines, and the first and second conductor lines are arranged co-planar with each other.

The switch may switch so that the second conductor line becomes a closed loop when the switch is turned on in response to the external control signal, and becomes an open loop when the switch is turned off in response to the external control signal.

Other features will become apparent to those skilled in the art from the following detailed description, which, taken in conjunction with the attached drawings, discloses exemplary embodiments of the invention.

### BRIEF DESCRIPTION OF THE DRAWINGS

FIG. 1 is a view illustrating the structure of an adjustable inductor according to an exemplary embodiment.

FIG. 2 is a view illustrating the structure of an adjustable inductor according to an exemplary embodiment.

FIG. 3A is an exemplary circuit diagram illustrating an equivalent circuit model in which the adjustable inductor of FIG. 1 has a switch turned off.

FIG. 3B is an exemplary circuit diagram illustrating an equivalent circuit model in which the adjustable inductor of FIG. 1 has a switch turned on.

FIG. 4 is a graphical representation of an inductance of an adjustable inductor according to an exemplary embodiment.

FIG. 5 illustrates the structure of a wideband voltage controlled oscillator according to an exemplary embodiment.

FIG. 6 illustrates a LC tank circuit for use in the wideband voltage controlled oscillator of FIG. 5 according to an exemplary embodiment.

Throughout the drawings and the detailed description, the same drawing reference numerals will be understood to refer to the same elements, features, and structures.

### DETAILED DESCRIPTION

The following detailed description is provided to assist the reader in gaining a comprehensive understanding of the methods, apparatuses and/or systems described herein. Accordingly, various changes, modifications, and equivalents of the systems, apparatuses and/or methods described herein will be suggested to those of ordinary skill in the art. Also, descriptions of well-known functions and constructions are omitted to increase clarity and conciseness.

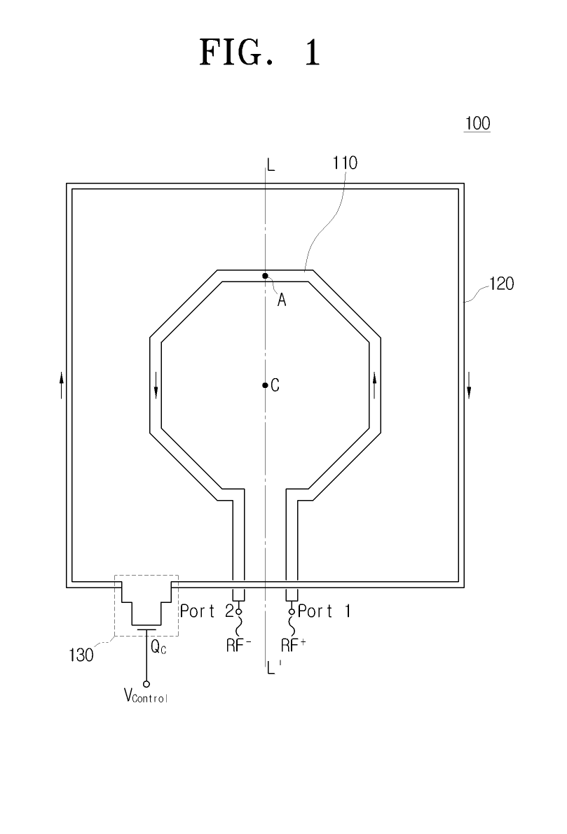

FIG. 1 illustrates an adjustable inductor according to an exemplary embodiment.

Referring to FIG. 1, the adjustable inductor 100 includes a first conductor line 110, a second conductor line 120, and a switch 130.

The first conductor line 110 is made from a conductive material such as, for example, metal to allow electric current to flow therethrough according to alternative current (AC) signal added to both ends. The first conductor line 110 may be configured to a loop form which has a center (C) therein. More specifically, the first conductor line 110 is supported on a substrate (not illustrated) and may be configured to a polygonal or circular loop in a symmetrical structure, both in vertical and horizontal directions, with respect to an imaginary line L-L′ crossing the center (C). A pair of differential signals (RF⁺, RF⁻) may be input as an AC signal. The pair of differential signals may be a pair of differential currents or voltages having 180° phase difference from each other.

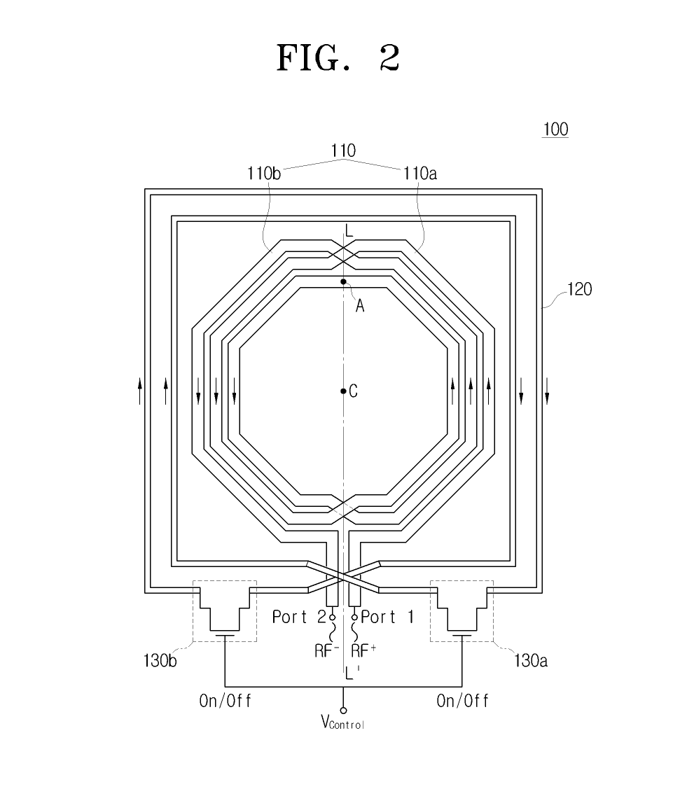

While FIG. 1 depicts the first conductor line 110 provided in a polygonal arrangement, it is understood that alternatives are possible. For example, the first conductor line 110 may be provided in a circular arrangement, or in multi-spiral arrangement as illustrated in FIG. 2 to increase the inductance variation.

The second conductor line 120 may be made from a conductor material such as metal to generate inducing current, in response to an AC signal applied to the first conductor line 110. Specifically, the second conductor line 120 may be configured in a square arrangement on the same plane, in a symmetrical structure with reference to an imaginary line L-L′. The second conductor line 120 is supported on a substrate (not illustrated), and may be placed co-planar with the first conductor line 110. Although FIG. 1 depicts that the second conductor line 120 configured in a square arrangement, the second conductor line 120 may be provided in various other configurations such as circle or polygon.

The switch 130 operates to switch a loop connection of the second conductor line 120 according to an external control signal, to adjust the inductance of the first conductor line 110. Specifically, the switch 130 is turned on or off in response to the external control signal to cause the second conductor line 120 to change between closed loop and open loop.

The switch 130 may be implemented as a transistor (Qc). The source of the transistor (Qc) is connected to one end of the second conductor line 120, and the drain is connected to the other end of the second conductor line 120. The gate of the transistor (Qc) is connected to an external control signal.

Where a control signal (Vcontrol) is applied to the gate of the transistor (Qc) in high level, the switch is turned on, thereby forming a path of electric current between the source and the drain and subsequently changing the second conductor line 120 to a close loop. Where a control signal (Vcontrol) is applied to the gate of the transistor (Qc) in low level, the switch is turned off, thereby opening the second conductor electrically, that is, changing the second conductor line 120 to an open loop.

The transistor (Qc) may be implemented as a N-channel metal-oxide semiconductor field effect transistor (MOSFET), but other alternatives are possible. For example, other switch elements may be implemented to selectively cause the second conductor line 120 to form a closed loop. Furthermore, while one transistor is used to construct a switch according to the above exemplary embodiment, one skilled in the art will understand that more than one transistors may also be applied to construct a switch.

FIG. 2 illustrates the structure of an adjustable inductor according to an exemplary embodiment.

Referring to FIG. 2, the first and second conductor lines 110 and 120 may be configured in multi-spiral arrangements, respectively.

The first conductor line 110 may be provided in a polygonal structure in which a radius is gradually decreased and then gradually increased from a predetermined location. In this case, the first conductor line 110 may include a first spiral conductor line 110a and a second spiral conductor line 110b.

One end of the first spiral conductor line 110a to receive one of AC inputs, is configured in an arrangement in which radius with respect to the center (C) is gradually decreased until a predetermined location (A). The second spiral conductor line 110b may be formed in an arrangement in which a radius is gradually increased from the predetermined location (A) until the other end to receive the second AC input. The first and second spiral lines 110a and 110b may be at a predetermined distance from each other, at a location where the two cross each other on the imaginary line (L-L′). The first and second spiral conductor lines 110a and 110b my desirably be arranged in a symmetrical relation with reference to the imaginary line (L-L′), and formed co-planar with each other, except at the location to cross each other on the imaginary line (L-L′).

The second conductor line 120 may be provided in a multi-spiral arrangement. Specifically, the second conductor line 120 may be formed in a symmetrical structure with reference to the imaginary line (L-L′), and formed co-planar with each other except at the location where the two cross each other on the imaginary line (L-L′).

According to an aspect, since the adjustable inductor 100 includes the first and second conductor lines 110 and 120 in multi-spiral arrangement, magnetic flux increases and inductance increases.

The operational principle of varying the inductance of the adjustable inductor 100 according to an exemplary embodiment will be explained below.

For example, where the switch 130 is turned off, an electric current by the AC signal flows only the first conductor line 110, while the second conductor line 120 is in open loop. Therefore, inducing current is not generated. In this situation, the inductance of the adjustable inductor 100 corresponds to that of the inductance having the first conductor line 110 alone.

Where the switch 130 is turned on, the second conductor line 120 forms a closed loop. In this case, if electric current by AC signal flows the first conductor line 110, inducing current flows the second conductor line 120 due to electromagnetic inducting phenomenon. According to the Lenz's Law, the direction of the inducing current is determined to apply in a direction to counterbalance the variation of the external magnetic field. Accordingly, where the electric current flows the first conductor line 110 in a counter-clockwise direction as illustrated in FIG. 1, the inducing current flows the second conductor line 120 in a clockwise direction. As a result, the electric currents have opposite directions. In other words, the magnetic flux by the current flowing the first conductor line 110, and the magnetic flux by the electric current flowing the second conductor line 120, have directions counterbalancing to each other, and the first and second conductor lines 110 and 120 form a negative mutual coupling. As a result, the adjustable inductor 100 has a decreased inductance compared to when the switch 130 is turned off.

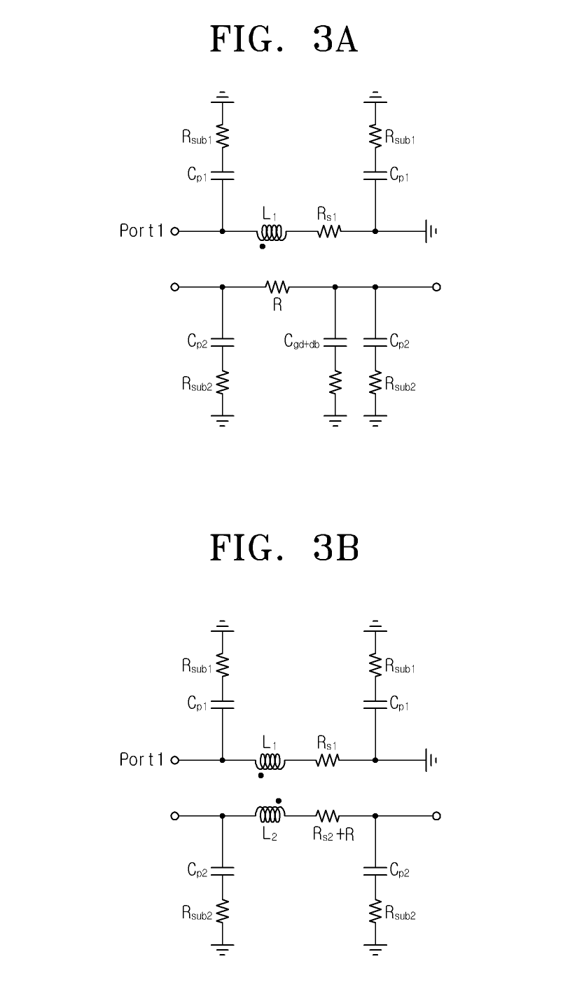

Accordingly, the adjustable inductor 100 according to an exemplary embodiment may easily vary the inductance according to a control signal. Referring to FIG. 1 or FIG. 2, the first and second conductor lines 110 and 120 of the adjustable inductor 100 are arranged co-planar to each other. Accordingly, the adjustable inductor 100 may provide improved quality factor, and may be small-sized.

Where a pair of differential signals (RF⁺, RF⁻) is applied to both ends of the conductor line as an AC signal, the middle portion of the conductor line operates as an imaginary round with respect to the AC component. Accordingly, the middle portion (A) of the first conductor line 110 operates as an imaginary ground, where the pair of differential signals (RF⁺, RF⁻) is applied to the first conductor line 110. The equivalent circuit model of the adjustable inductor of FIG. 3 will be explained below in view of the above.

FIG. 3A illustrates an exemplary equivalent circuit model of the adjustable inductor of FIG. 2 in which a switch is turned off, and FIG. 3B is an exemplary circuit diagram of an equivalent circuit model of the adjustable inductor of FIG. 2 in which a switch is turned on.

Referring to FIGS. 3A and 3B, the reference symbol ‘Rsub1’ denotes a parasite resistance between the first spiral conductor line 110a and the substrate (not illustrated), and ‘Rsub2’ denotes a parasite resistance between the second spiral conductor line 110b and the substrate. The reference symbol ‘Cp1 ’ denotes a parasite capacitance between the first spiral conductor line 110a and the substrate (not illustrated), and ‘Cp2′ denotes a parasite capacitance between the second conductor line 120 and the substrate. The reference symbol ‘Rs1’ denotes a serial resistance of the first spiral conductor line 110a, and ‘Rs2’ denotes a serial resistance of the second conductor line 120. The reference symbol ‘Rs2’ denotes a serial resistance between one end of the second conductor line 120 and a middle portion, that is, the imaginary ground, of the second conductor 120, and ‘R’ denotes a resistance of the switch 130 which is as low as 2.5Ω when in on state, but goes to infinity when in off state. The reference symbol ‘Cgd+db’ denotes a parasite capacitance obtained when the switch 130 is turned off.

The influence due to the parasite resistance, parasite capacitance and resistance of the switch 130 in on state, is considerably lower than that by the inductance of the first and second conductor lines 110 and 120, and thus may be neglected.

Accordingly, where the switch 130 is turned off, the adjustable inductor 100 has the characteristics of a circuit in which an inductor L1 corresponding to the first spiral conductor line 110a is arranged between port 1 and the imaginary ground VG, and an inductor L1′ (not illustrated) corresponding to the second spiral conductor line 110b is arranged between port 2 and the imaginary ground VG. The first and second spiral conductor lines 110a and 110b are in symmetrical relation with reference to the imaginary line (L-L′), but FIGS. 3A and 3B illustrate only the circuit corresponding to the first spiral conductor line 110a as an example for convenience of explanation.

Where the switch 130 is turned on, as illustrated in the adjustable inductor 100 of FIG. 3B, the inductor L1 corresponding to the first spiral conductor line 110a and the inductor L2 corresponding to a portion of the second spiral line 120 from one end to a middle portion B, form a negative mutual coupling. Since the inductors L1 and L2 form negative mutual coupling, the inductance is lower than when the switch 130 is turned off.

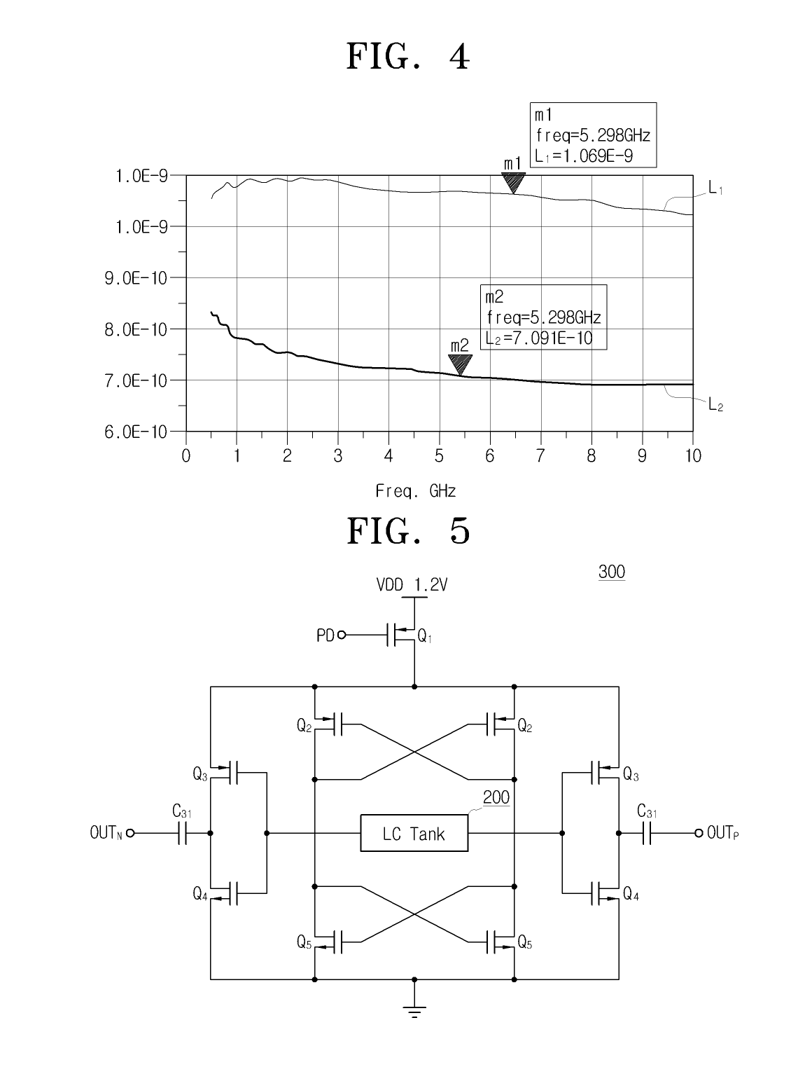

FIG. 4 is a graphical representation of the inductance of the adjustable inductor according to an exemplary embodiment. The adjustable inductor has 1.07*10⁻⁹ H when the switch is on, and has 7.09*10⁻¹⁰ H when the switch is off. As a result, 30% of inductance change is obtained.

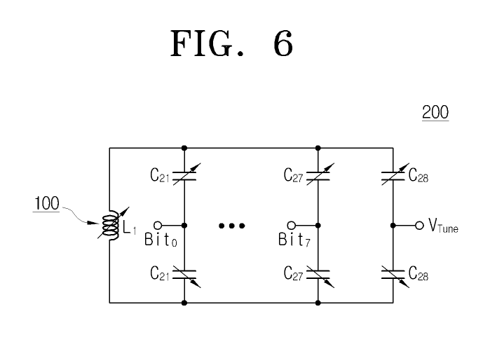

FIG. 5 illustrates the structure of a wideband voltage controlled oscillator according to an exemplary embodiment, and FIG. 6 illustrates an example of a LC tank circuit 200 for use in the wideband voltage controlled oscillator 300 of FIG. 5.

Referring to FIGS. 5 and 6, the voltage controlled oscillator 300 includes adjustable capacitors C₂₁-C₂₈, an adjustable inductor 100, and an adjuster (not illustrated).

The adjustable inductor 100 provides an inductance in response to an AC signal, and may vary the inductance by selectively using the inducing current generated by the AC signal. The adjustable inductor 100 may be connected in parallel to the adjustable capacitors C₂₁-C₂₈, to form the LC tank 200 (FIG. 5) and generate an oscillation frequency. The adjustable inductor 100 may be implemented in the arrangement illustrated in FIG. 1 or FIG. 2.

The adjuster (not illustrated) adjusts the oscillation frequency by varying the capacitance of the adjustable capacitor C₂₁-C₂₈ and the inductance of the adjustable inductor 100. Specifically, the adjuster (not illustrated) turns on/off the switch 130 of the adjustable inductor 100. As a result, the oscillation frequency is varied in a wider width as the inductance of the adjustable inductor 100 is varied. The adjuster (not illustrated) may also minutely vary the oscillation frequency by varying the adjustable capacitors C₂₁-C₂₈, and output the result.

In the voltage controlled oscillator 300 according to certain exemplary embodiments, the oscillating circuit is implemented by using one adjustable inductor 100, and thus may be small-sized.

A number of exemplary embodiments have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. An adjustable inductor comprising:
a first conductor line to receive an alternating current (AC) signal;
a second conductor line configured in a loop arrangement, to generate an inducting current upon receiving the AC signal at the first conductor line; and
a switch to adjust an inductance of the first conductor line by switching a loop connection of the second conductor line according to an external control signal.

2. The adjustable inductor of claim 1, wherein the first conductor line is arranged within the second conductor line and configured in a loop arrangement.

3. The adjustable inductor of claim 2, wherein the first conductor line is configured in a symmetrical arrangement, both vertically and horizontally, with reference to an imaginary line crossing a center.

4. The adjustable inductor of claim 1, wherein the first conductor line is arranged co-planar with the second conductor line, and configured in a multi-spiral structure.

5. The adjustable inductor of claim 1, wherein the second conductor line is configured in a symmetrical arrangement, both vertically and horizontally, with reference to an imaginary line crossing a center.

6. The adjustable inductor of claim 5, further comprising a substrate to support the first and second conductor lines, wherein the first and second conductor lines are arranged co-planar with each other.

7. The adjustable inductor of claim 1, wherein the switch switches so that the second conductor line becomes a closed loop when the switch is turned on in response to the external control signal, and becomes an open loop when the switch is turned off in response to the external control signal.

8. A wideband voltage controlled oscillator comprising:
an adjustable capacitor;
an adjustable inductor to provide an inductance in response to an alternating current (AC) signal, and to vary the inductance by selectively using an inducing current generated in response to the AC signal; and
an adjuster to vary an oscillation frequency by varying a capacitance of the adjustable capacitor and an inductance of the adjustable inductor.

9. The wideband voltage controlled oscillator of claim 8, wherein the adjustable inductor comprises:
a first conductor line to receive the AC signal;
a second conductor line configured in a loop arrangement, to generate an inducing current in response to the AC signal received at the first conductor line; and
a switch to adjust an inductance of the first conductor line, by switching a loop connection of the second conductor line in accordance with a control signal applied from the adjuster.

10. The wideband voltage controlled oscillator of claim 9, wherein the first conductor line is arranged within the second conductor line, and configured in a loop arrangement.

11. The wideband voltage controlled oscillator of claim 10, wherein the first conductor line is configured in a symmetrical arrangement, both vertically and horizontally, with reference to an imaginary line crossing a center.

12. The wideband voltage controlled oscillator of claim 9, wherein the first conductor line is arranged co-planar with the second conductor line, and configured in a multi-spiral structure.

13. The wideband voltage controlled oscillator of claim 9, wherein the second conductor line is configured in a symmetrical arrangement, both vertically and horizontally, with reference to an imaginary line crossing a center.

14. The wideband voltage controlled oscillator of claim 13, wherein the adjustable inductor further comprises a substrate to support the first and second conductor lines, and the first and second conductor lines are arranged co-planar with each other.

15. The wideband voltage controlled oscillator of claim 9, wherein the switch switches so that the second conductor line becomes a closed loop when the switch is turned on in response to the external control signal, and becomes an open loop when the switch is turned off in response to the external control signal.
